(19) United States
(12) Patent Application Publication
(10) Pub. No.: US 2025/0201595 A1
(43) Pub. Date: Jun. 19, 2025

(54) HEAT TREATMENT APPARATUS AND HEAT TREATMENT METHOD FOR HEATING SUBSTRATE BY LIGHT IRRADIATION

(71) Applicant: SCREEN Holdings Co., Ltd., Kyoto (JP)

(72) Inventor: Kazuhiko FUSE, Kyoto-shi (JP)

(21) Appl. No.: 18/976,217

(22) Filed: Dec. 10, 2024

(30) Foreign Application Priority Data
Dec. 15, 2023 (JP) 2023-212047

(51) Int. Cl. H01L 21/67

(52) U.S. Cl. CPC H01L 21/67115; H01L 21/67017; H01L 21/67184

(57) ABSTRACT

Heating treatment is performed by irradiating a semiconductor wafer with light in a reduced pressure atmosphere in a treatment chamber. Pressure in the treatment chamber is set to a base pressure that is a fixed value lower than atmospheric pressure when the semiconductor wafer is transported into and out of the treatment chamber. The pressure in the treatment chamber is less than the base pressure when the heating treatment is performed on the semiconductor wafer. Since the pressure in the treatment chamber is always maintained below atmospheric pressure, even if pressure variations in the treatment chamber overshoot more or less from the base pressure, the inside of the treatment chamber is always under a negative pressure relative to the outside of an apparatus. This prevents gas from leaking out of the treatment chamber.

### BACKGROUND OF THE INVENTION

### Field of the Invention

The present invention relates to a heat treatment apparatus and a heat treatment method which irradiate a substrate with light to heat the substrate. Examples of the substrate to be treated include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

The flash lamp annealing such as for impurity activation is performed in an atmosphere of atmospheric pressure. However, depending on the details of the process, the flash lamp annealing is performed in some cases while supplying a specific treatment gas (e.g., ammonia, ozone, or the like) in a reduced-pressure atmosphere in which the pressure in a treatment chamber is reduced to, for example, approximately 5 to 50 kPa (as disclosed in, for example, U.S. Patent Application Publication No. 2017/0062249). On the other hand, the transfer of semiconductor wafers to and from the treatment chamber in which the flash lamp annealing is performed is required to be performed at atmospheric pressure because the pressure in each chamber responsible for the transport of semiconductor wafers is always atmospheric. It is hence necessary to reduce the pressure in the treatment chamber with a vacuum pump after a semiconductor wafer is transported into the treatment chamber and to return the pressure in the treatment chamber to the atmospheric pressure by supplying nitrogen or the like after the annealing process.

When nitrogen or the like is supplied into the treatment chamber in a reduced-pressure atmosphere to return the pressure in the treatment chamber to the atmospheric pressure, pressure variations overshoot in some cases to result in a positive pressure in the treatment chamber in which the pressure is unintentionally higher than outside pressure. If the pressure in the treatment chamber becomes positive, there is a danger that ammonia or other harmful gases may leak out of the treatment chamber to the outside.

In addition, if the pressure in the treatment chamber is repeatedly reduced and returned each time a semiconductor wafer is treated, there is a danger that parts such as O-rings may deteriorate and break in a relatively short time, so that the treatment gas leaks out of the damaged locations to the outside.

### SUMMARY

The present invention is intended for a heat treatment apparatus for heating a substrate by irradiating the substrate with light.

According to one aspect of the present invention, the heat treatment apparatus comprises: a treatment chamber for receiving a substrate therein to perform heating treatment on the substrate; a holder for holding the substrate in the treatment chamber; a light source for irradiating the substrate received in the treatment chamber with light; a gas supply part for supplying a treatment gas to the treatment chamber; an exhaust part for exhausting an atmosphere from the treatment chamber; and a controller for controlling the gas supply part and the exhaust part so that a target pressure is reached in the treatment chamber, wherein the controller controls the gas supply part and the exhaust part so that pressure in the treatment chamber is always maintained at or below a reference pressure that is a fixed value lower than atmospheric pressure and so that the pressure in the treatment chamber is a treatment pressure lower than the reference pressure during the heating treatment of the substrate.

The inside of the treatment chamber is always under a negative pressure relative to the outside of the apparatus. This prevents gas from leaking out of the treatment chamber.

Preferably, the heat treatment apparatus further comprises a cool chamber connected to the transport chamber and for temporarily holding an untreated substrate to be transported to the transport chamber and for temporarily holding and cooling a substrate subjected to the heating treatment and transported from the transport chamber, wherein the cool chamber has a volume smaller than that of the transport chamber, and wherein pressure in the cool chamber is reduced from the atmospheric pressure to the reference pressure when the untreated substrate is held in the cool chamber after transported into the cool chamber, and the pressure in the cool chamber is returned from the reference pressure to the atmospheric pressure when the substrate subjected to the heating treatment is held in the cool chamber after transported into the cool chamber.

The pressure adjustment in the cool chamber allows the adjustment in a short time.

The present invention is also intended for a method of heating a substrate by irradiating the substrate with light.

According to one aspect of the present invention, the method comprises the steps of: (a) receiving a substrate in a treatment chamber; (b) reducing pressure in the treatment chamber receiving the substrate therein; (c) irradiating the substrate with light; and (d) returning the pressure in the treatment chamber, wherein the pressure in the treatment chamber is always maintained at or below a reference pressure that is a fixed value lower than atmospheric pressure, and wherein the pressure in the treatment chamber in the step (c) is a treatment pressure lower than the reference pressure.

The inside of the treatment chamber is always under a negative pressure relative to the outside of the apparatus. This prevents gas from leaking out of the treatment chamber.

Preferably, a cool chamber connected to the transport chamber temporarily holds an untreated substrate to be transported to the transport chamber and temporarily holds and cools a substrate subjected to the heating treatment and transported from the transport chamber; the cool chamber has a volume smaller than that of the transport chamber; and pressure in the cool chamber is reduced from the atmospheric pressure to the reference pressure when the untreated substrate is held in the cool chamber after transported into the cool chamber, and the pressure in the cool chamber is increased from the reference pressure to the atmospheric pressure when the substrate subjected to the heating treatment is held in the cool chamber after transported into the cool chamber.

The pressure adjustment in the cool chamber allows the adjustment in a short time.

It is therefore an object of the present invention to prevent gas from leaking out of a treatment chamber.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a heat treatment apparatus according to the present invention;

FIG. 2 is a front view of the heat treatment apparatus of FIG. 1:

FIG. 3 is a longitudinal sectional view showing a configuration of a heat treatment part;

FIG. 4 is a perspective view showing the entire external appearance of a holder;

FIG. 5 is a plan view of a susceptor;

FIG. 6 is a sectional view of the susceptor;

FIG. 7 is a plan view of a transfer mechanism;

FIG. 8 is a side view of the transfer mechanism;

FIG. 9 is a plan view showing an arrangement of halogen lamps;

FIG. 10 is a schematic view of supply and exhaust systems for the heat treatment apparatus;

FIG. 11 is a graph showing pressure variations in a treatment chamber; and

FIG. 12 is a graph showing a relationship between the pressures in an indexer part, cool chambers, a transport chamber, and the treatment chamber.

### DESCRIPTION OF THE PREFERRED EMBODIMENTS

A preferred embodiment according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

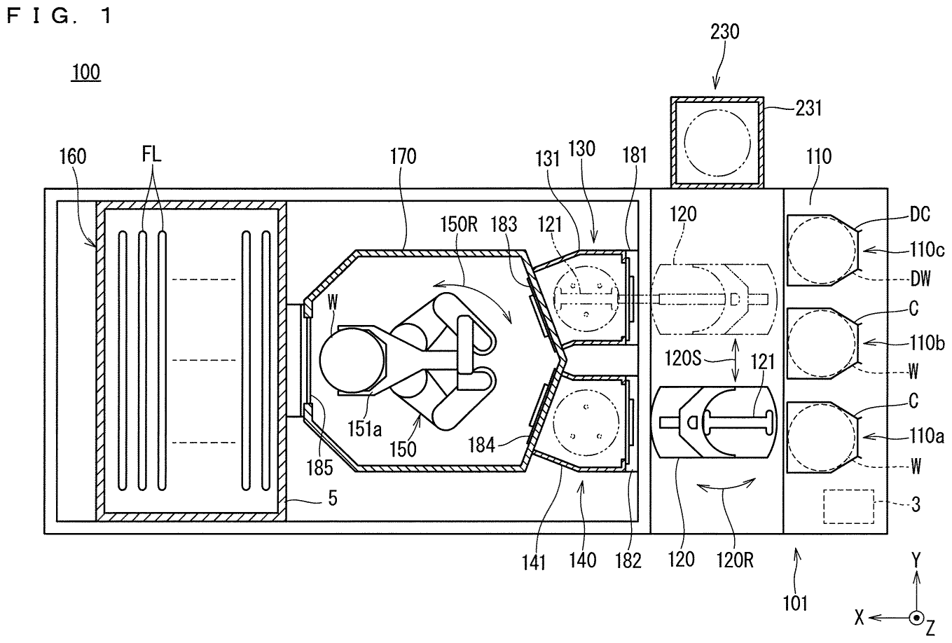

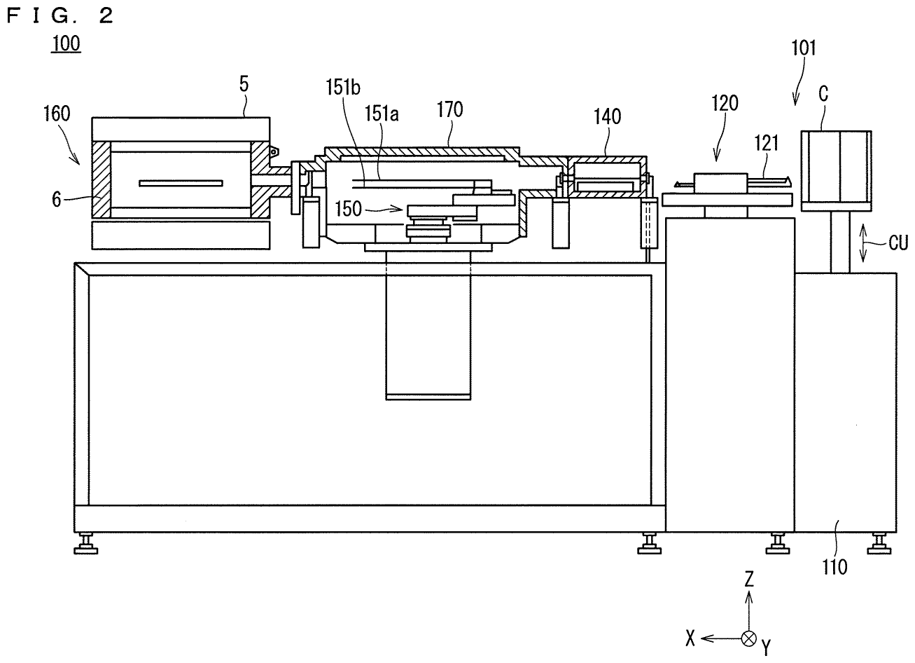

First, an example of the configuration of a heat treatment apparatus according to the present invention will be described. FIG. 1 is a plan view of a heat treatment apparatus 100, and FIG. 2 is a front view of the heat treatment apparatus 100. The heat treatment apparatus 100 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm. It should be noted that the dimensions of components and the number of components are shown in exaggeration or in simplified form, as appropriate, in FIG. 1 and the subsequent figures for the sake of easier understanding. An XYZ rectangular coordinate system in which an XY plane is defined as a horizontal plane and a Z axis is defined to extend in a vertical direction is additionally shown in FIGS. 1 to 3 for purposes of clarifying the directional relationship therebetween.

As shown in FIGS. 1 and 2, the heat treatment apparatus 100 includes: an indexer part 101 for transporting untreated semiconductor wafers W from the outside into the heat treatment apparatus 100 and for transporting treated semiconductor wafers W to the outside of the heat treatment apparatus 100; an alignment part 230 for positioning an untreated semiconductor wafer W; a first cooling part 130 and a second cooling part 140 each for cooling a semiconductor wafer W subjected to heating treatment; a heat treatment part 160 for performing flash heating treatment on a semiconductor wafer W; and a transport robot 150 for transferring a semiconductor wafer W to and from the first cooling part 130, the second cooling part 140, and the heat treatment part 160. The heat treatment apparatus 100 further includes a controller 3 for controlling operating mechanisms provided in the aforementioned processing parts and the transport robot 150 to cause the flash heating treatment of the semiconductor wafer W to proceed.

The indexer part 101 includes: a load port 110 for placing thereon a plurality of carriers (or cassettes) C arranged in juxtaposition; and a transfer robot 120 for taking an untreated semiconductor wafer W out of each of the carriers C and for storing a treated semiconductor wafer W into each of the carriers C. To be precise, the indexer part 101 includes three load ports, and the load port 110 is a collective designation for a first load port 110a, a second load port 110b, and a third load port 110c. (The three load ports 110a, 110b, and 110c are collectively referred to as the load port 110, unless otherwise identified.) Carriers C in which semiconductor wafers W (product wafers) that become products are stored are placed on the first load port 110a and the second load port 110b. On the other hand, the third load port 110c is a load port exclusive to a dummy carrier DC in which dummy wafers DW are stored. That is, only the dummy carrier DC is placed on the third load port 110c. The dummy wafers DW are wafers having the same shape and material as the product wafers but are not treated as products.

An unmanned transport vehicle (an AGV (automatic guided vehicle) or an OHT (overhead hoist transfer)) or the like transports a carrier C with untreated semiconductor wafers W stored therein and the dummy carrier DC to place the carrier C and the dummy carrier DC on the load port 110. The carriers C and the dummy carrier DC are tagged for identification, and the tags on the carriers C and the dummy carrier DC placed on the load port 110 are read by a tag reader not shown. The unmanned transport vehicle also carries a carrier C with treated semiconductor wafers W stored therein and the dummy carrier DC away from the load port 110.

In the load port 110, the carriers C and the dummy carrier DC are movable upwardly and downwardly as indicated by an arrow CU in FIG. 2 so that the transfer robot 120 is able to load any semiconductor wafer W (or any dummy wafer DW) into each of the carriers C and the dummy carrier DC and unload any semiconductor wafer W (or any dummy wafer DW) from each of the carriers C and the dummy carrier DC. The carriers C and the dummy carrier DC may be of the following types: an SMIF (standard mechanical interface) pod and an OC (open cassette) which exposes stored semiconductor wafer W to the outside atmosphere, in addition to a FOUP (front opening unified pod) which stores semiconductor wafer W in an enclosed or sealed space.

The transfer robot 120 is slidable as indicated by an arrow 120S in FIG. 1, pivotable as indicated by an arrow 120R in FIG. 1, and movable upwardly and downwardly. Thus, the transfer robot 120 loads and unloads semiconductor wafers W into and from the carriers C and the dummy carrier DC, and transfers semiconductor wafers W to and from the alignment part 230 and the two cooling parts (the first cooling part 130 and the second cooling part 140). The operation of the transfer robot 120 loading and unloading the semiconductor wafers W into and from the carriers C (or the dummy carrier DC) is achieved by the sliding movement of a hand 121 of the transfer robot 120 and the upward and downward movement of the carriers C. The transfer of the semiconductor wafers W between the transfer robot 120 and the alignment part 230, between the transfer robot 120 and the first cooling part 130, or between the transfer robot 120 and the second cooling part 140 is achieved by the sliding movement of the hand 121 and the upward and downward movement of the transfer robot 120.

The alignment part 230 is provided on and connected to one side of the indexer part 101 in adjacent relation thereto along the Y axis. The alignment part 230 is a processing part for rotating a semiconductor wafer W in a horizontal plane to an orientation appropriate for flash heating. The alignment part 230 includes an alignment chamber 231 which is a housing made of an aluminum alloy, a mechanism provided in the alignment chamber 231 and for supporting and rotating a semiconductor wafer W in a horizontal attitude, a mechanism provided in the alignment chamber 231 and for optically detecting a notch, an orientation flat, and the like formed in a peripheral portion of a semiconductor wafer W, and the like.

The transfer robot 120 transfers a semiconductor wafer W to and from the alignment part 230. The semiconductor wafer W is transferred from the transfer robot 120 to the alignment chamber 231 so that the center of the semiconductor wafer W is positioned at a predetermined position. The alignment part 230 rotates the semiconductor wafer W received from the indexer part 101 about a vertical axis passing through the central portion of the semiconductor wafer W to optically detect a notch and the like, thereby adjusting the orientation of the semiconductor wafer W. The semiconductor wafer W subjected to the orientation adjustment is taken out of the alignment chamber 231 by the transfer robot 120.

A transport chamber 170 for housing the transport robot 150 therein is provided as space for transport of the semiconductor wafer W by means of the transport robot 150. A treatment chamber 6 in the heat treatment part 160, a first cool chamber 131 in the first cooling part 130, and a second cool chamber 141 in the second cooling part 140 are connected to three sides of the transport chamber 170.

The heat treatment part 160 which is a principal part of the heat treatment apparatus 100 is a substrate processing part for irradiating a preheated semiconductor wafer W with flashes of light from xenon flash lamps FL to perform flash heating treatment on the semiconductor wafer W. The configuration of the heat treatment part 160 will be described later in detail.

The first cooling part 130 and the second cooling part 140 are substantially similar in configuration to each other. The first and second cooling parts 130 and 140 include respective metal cooling plates and respective quartz plates (both not shown) placed on the upper surfaces of the cooling plates in the first and second cool chambers 131 and 141 which are housings made of an aluminum alloy. Each of the cooling plates is temperature-controlled at ordinary temperatures (approximately 23° C.) by a Peltier element or by circulation of constant-temperature water. The semiconductor wafer W subjected to the flash heating treatment in the heat treatment part 160 is transported into the first cool chamber 131 or the second cool chamber 141, and is then placed and cooled on a corresponding one of the quartz plate.

The first cool chamber 131 and the second cool chamber 141 provided between the indexer part 101 and the transport chamber 170 are connected to both the indexer part 101 and the transport chamber 170. Each of the first cool chamber 131 and the second cool chamber 141 has two openings for transporting the semiconductor wafer W thereinto and therefrom. One of the openings of the first cool chamber 131 which is connected to the indexer part 101 is openable and closable by a gate valve 181. The other opening of the first cool chamber 131 which is connected to the transport chamber 170 is openable and closable by a gate valve 183. In other words, the first cool chamber 131 and the indexer part 101 are connected to each other through the gate valve 181, and the first cool chamber 131 and the transport chamber 170 are connected to each other through the gate valve 183.

The gate valve 181 is opened when the semiconductor wafer W is transferred between the indexer part 101 and the first cool chamber 131. The gate valve 183 is opened when the semiconductor wafer W is transferred between the first cool chamber 131 and the transport chamber 170. When the gate valve 181 and the gate valve 183 are closed, the interior of the first cool chamber 131 is an enclosed space.

One of the two openings of the second cool chamber 141 which is connected to the indexer part 101 is openable and closable by a gate valve 182. The other opening of the second cool chamber 141 which is connected to the transport chamber 170 is openable and closable by a gate valve 184. In other words, the second cool chamber 141 and the indexer part 101 are connected to each other through the gate valve 182, and the second cool chamber 141 and the transport chamber 170 are connected to each other through the gate valve 184.

The gate valve 182 is opened when the semiconductor wafer W is transferred between the indexer part 101 and the second cool chamber 141. The gate valve 184 is opened when the semiconductor wafer W is transferred between the second cool chamber 141 and the transport chamber 170. When the gate valve 182 and the gate valve 184 are closed, the interior of the second cool chamber 141 is an enclosed space. The volume of the first cool chamber 131 and the second cool chamber 141 is smaller than that of the transport chamber 170, and is approximately 1/10 that of the transport chamber 170.

The transport robot 150 provided in the transport chamber 170 is pivotable about a vertical axis as indicated by an arrow 150R. The transport robot 150 includes two linkage mechanisms comprised of a plurality of arm segments. Transport hands 151a and 151b each for holding a semiconductor wafer W are provided at respective distal ends of the two linkage mechanisms. These transport hands 151a and 151b are vertically spaced a predetermined distance apart from each other, and are independently linearly slidable in the same horizontal direction by the respective linkage mechanisms. The transport robot 150 moves a base provided with the two linkage mechanisms upwardly and downwardly to thereby move the two transport hands 151a and 151b spaced the predetermined distance apart from each other upwardly and downwardly.

When the transport robot 150 transfers (loads and unloads) a semiconductor wafer W to and from the first cool chamber 131, the second cool chamber 141, or the treatment chamber 6 in the heat treatment part 160 as a transfer target, both of the transport hands 151a and 151b pivot into opposed relation to the transfer target, and move upwardly or downwardly after (or during) the pivotal movement, so that one of the transport hands 151a and 151b reaches a vertical position at which the semiconductor wafer W is to be transferred to and from the transfer target. Then, the transport robot 150 causes the transport hand 151a (or 151b) to linearly slide in a horizontal direction, thereby transferring the semiconductor wafer W to and from the transfer target.

The transfer of a semiconductor wafer W between the transport robot 150 and the transfer robot 120 is performed through the first cooling part 130 or the second cooling part 140. That is, the first cool chamber 131 in the first cooling part 130 and the second cool chamber 141 in the second cooling part 140 function also as paths for transferring a semiconductor wafer W between the transport robot 150 and the transfer robot 120. Specifically, one of the transport robot 150 and the transfer robot 120 transfers a semiconductor wafer W to the first cool chamber 131 or the second cool chamber 141, and the other of the transport robot 150 and the transfer robot 120 receives the semiconductor wafer W, whereby the transfer of the semiconductor wafer W is performed. The transport robot 150 and the transfer robot 120 constitute a transport mechanism for transporting a semiconductor wafer W from the carriers C to the heat treatment part 160.

As mentioned above, the gate valves 181 and 182 are provided between the indexer part 101 and the first and second cool chambers 131 and 141, respectively. The gate valves 183 and 184 are provided between the transport chamber 170 and the first and second cool chambers 131 and 141, respectively. A gate valve 185 is further provided between the transport chamber 170 and the treatment chamber 6 of the heat treatment part 160. These gate valves 181 to 185 are opened and closed, as appropriate, when the semiconductor wafer W is transported in the heat treatment apparatus 100.

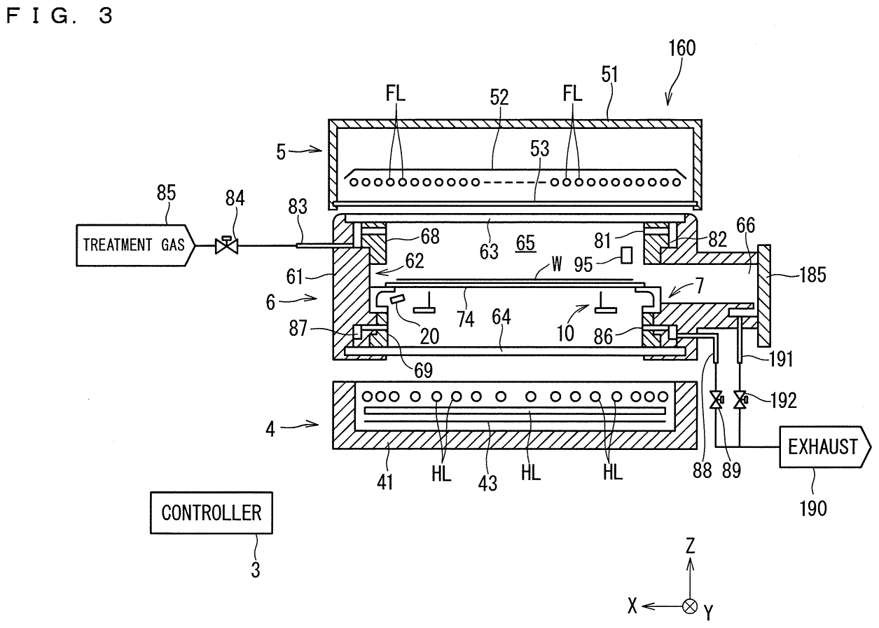

Next, the configuration of the heat treatment part 160 will be described. FIG. 3 is a longitudinal sectional view showing the configuration of the heat treatment part 160. The heat treatment part 160 includes the treatment chamber 6 for receiving a semiconductor wafer W therein to perform heating treatment on the semiconductor wafer W, a flash lamp house 5 including the plurality of built-in flash lamps FL, and a halogen lamp house 4 including a plurality of built-in halogen lamps HL. The flash lamp house 5 is provided over the treatment chamber 6, and the halogen lamp house 4 is provided under the treatment chamber 6. The heat treatment part 160 further includes a holder 7 provided inside the treatment chamber 6 and for holding a semiconductor wafer W in a horizontal attitude, and a transfer mechanism 10 provided inside the treatment chamber 6 and for transferring a semiconductor wafer W between the holder 7 and the transport robot 150.

The treatment chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the treatment chamber 6 is a disk-shaped member made of quartz, and serves as a quartz window that transmits flashes of light emitted from the flash lamps FL therethrough into the treatment chamber 6. The lower chamber window 64 forming the floor of the treatment chamber 6 is also a disk-shaped member made of quartz, and serves as a quartz window that transmits light emitted from the halogen lamps HL therethrough into the treatment chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the treatment chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the treatment chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the treatment chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the treatment chamber 6. The transport opening 66 is openable and closable by the gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the treatment chamber 6 is an enclosed space.

At least one gas supply opening 81 for supplying a treatment gas therethrough into the heat treatment space 65 is provided in an upper portion of the inner wall of the treatment chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the treatment chamber 6. The gas supply pipe 83 is connected to a treatment gas supply source 85. A supply valve 84 is interposed in the gas supply pipe 83. When the supply valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N₂), and reactive gases such as ozone (O₃), hydrogen (H₂) and ammonia (NH₃).

At least one gas exhaust opening 86 for exhausting a gas from the heat treatment space 65 is provided in a lower portion of the inner wall of the treatment chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the treatment chamber 6. The gas exhaust pipe 88 is connected to an exhaust mechanism 190. An exhaust valve 89 is interposed in the gas exhaust pipe 88. When the exhaust valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the treatment chamber 6, and may be in the form of slits. The treatment gas supply source 85 and the exhaust mechanism 190 may be mechanisms provided in the heat treatment apparatus 100 or be utility systems in a factory in which the heat treatment apparatus 100 is installed.

A gas exhaust pipe 191 for exhausting the gas from the heat treatment space 65 is also connected to a distal end of the transport opening 66. The gas exhaust pipe 191 is connected through a valve 192 to the exhaust mechanism 190. By opening the valve 192, the gas in the treatment chamber 6 is exhausted through the transport opening 66.

The exhaust mechanism 190 has a vacuum pump. By opening the exhaust valve 89 while closing the supply valve 84 and exhausting the atmosphere in the treatment chamber 6 by means of the vacuum pump, the pressure in the treatment chamber 6 is reduced to less than atmospheric pressure. The treatment chamber 6 is provided with a pressure gauge 95. The pressure gauge 95 is capable of measuring the pressure in the treatment chamber 6.

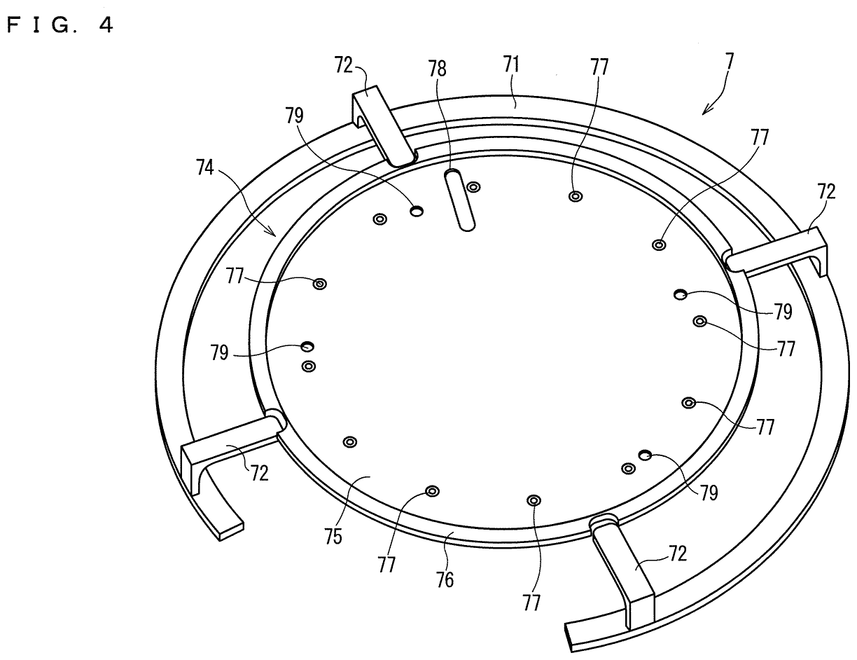

FIG. 4 is a perspective view showing the entire external appearance of the holder 7. The holder 7 includes a base ring 71, coupling portions 72, and a susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the treatment chamber 6 by being placed on the bottom surface of the recessed portion 62 (with reference to FIG. 3). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

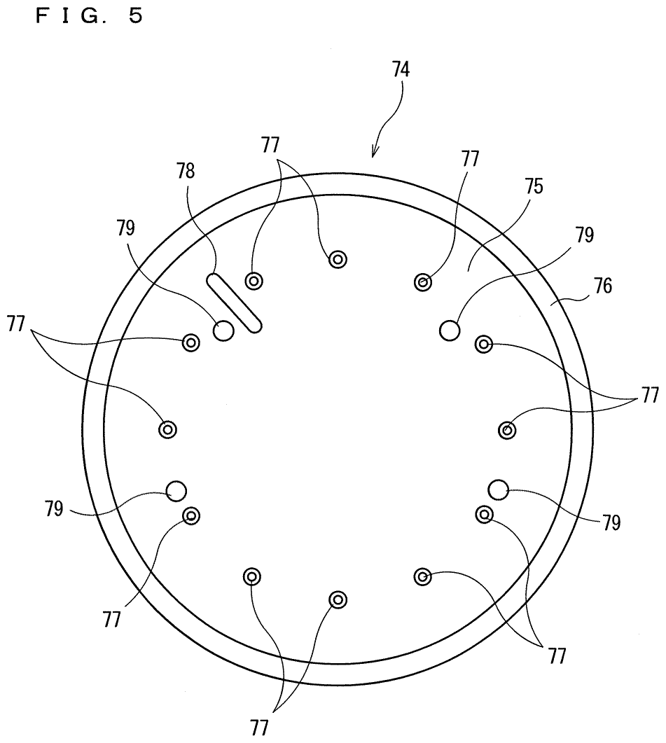

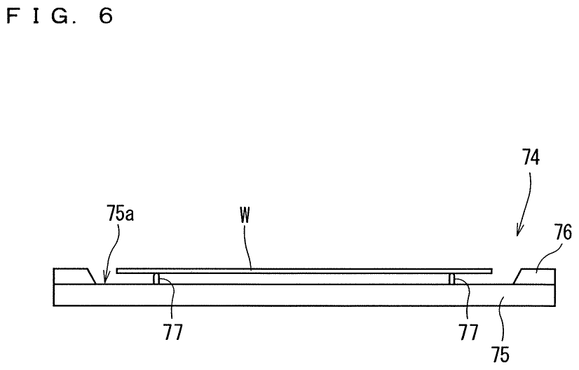

The susceptor 74 is supported by the four coupling portions 72 provided on the base ring 71. FIG. 5 is a plan view of the susceptor 74. FIG. 6 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 4, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the treatment chamber 6, whereby the holder 7 is mounted to the treatment chamber 6. With the holder 7 mounted to the treatment chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the treatment chamber 6 is placed and held in a horizontal attitude on the susceptor 74 of the holder 7 mounted to the treatment chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 4 and 5, an opening 78 is provided in the holding plate 75 of the susceptor 74 so as to extend vertically through the holding plate 75 of the susceptor 74. The opening 78 is provided for a radiation thermometer 20 (with reference to FIG. 3) to receive radiation (infrared radiation) emitted from the lower surface of the semiconductor wafer W held by the susceptor 74. Specifically, the radiation thermometer 20 receives the radiation emitted from the lower surface of the semiconductor wafer W held by the susceptor 74 through the opening 78 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

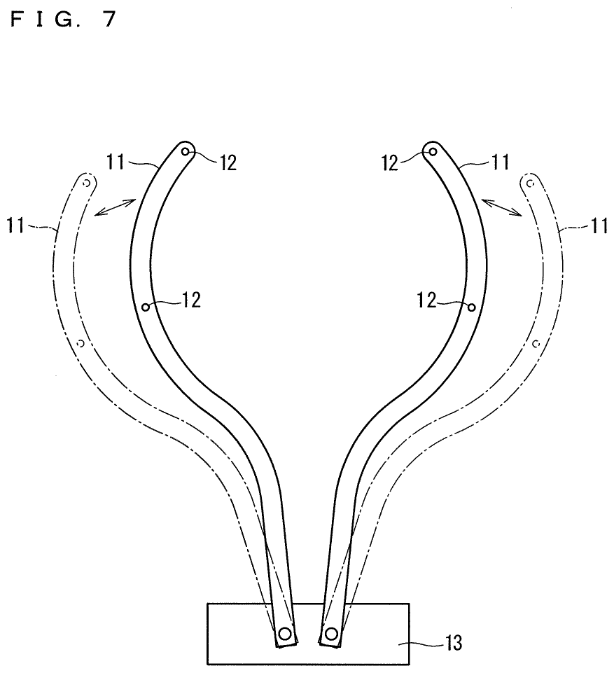

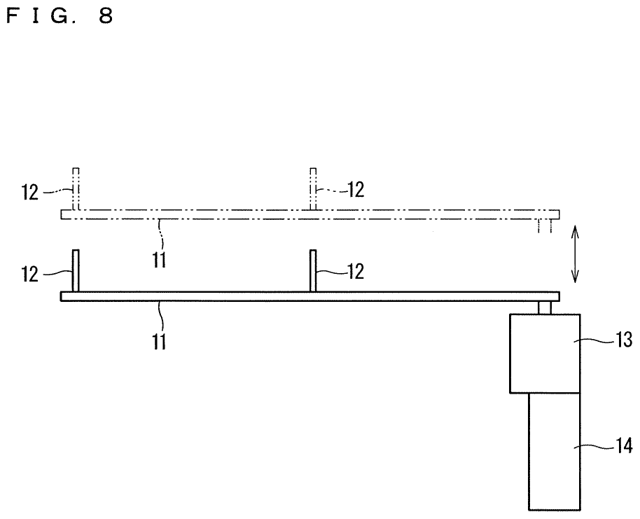

FIG. 7 is a plan view of the transfer mechanism 10. FIG. 8 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 are pivotable by a horizontal movement mechanism 13. The horizontal movement mechanism 13 moves the pair of transfer arms 11 horizontally between a transfer operation position (a position indicated by solid lines in FIG. 7) in which a semiconductor wafer W is transferred to and from the holder 7 and a retracted position (a position indicated by dash-double-dot lines in FIG. 7) in which the transfer arms 11 do not overlap the semiconductor wafer W held by the holder 7 as seen in plan view. The transfer operation position is under the susceptor 74, and the retracted position is outside the susceptor 74. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 4 and 5) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the treatment chamber 6.

Referring again to FIG. 3, the heat treatment part 160 includes the radiation thermometer 20 and the pressure gauge 95 as measuring devices. The radiation thermometer 20 is provided obliquely below the semiconductor wafer W held by the susceptor 74. The radiation thermometer 20 is a wafer thermometer which receives the infrared radiation emitted from the lower surface of the semiconductor wafer W through the opening 78 of the susceptor 74 to measure the temperature of the semiconductor wafer W, based on the intensity of the infrared radiation. The pressure gauge 95 measures the pressure inside the treatment chamber 6. The radiation thermometer 20 and the pressure gauge 95 are shown inside the treatment chamber 6 in FIG. 3 for convenience of illustration, but are both mounted on the wall surface of the treatment chamber 6.

The flash lamp house 5 provided over the treatment chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash lamp house 5 further includes a lamp light radiation window 53 mounted to the bottom of the enclosure 51. The lamp light radiation window 53 forming the floor of the flash lamp house 5 is a plate-like quartz window made of quartz. The flash lamp house 5 is provided over the treatment chamber 6, whereby the lamp light radiation window 53 is opposed to the upper chamber window 63. The flash lamps FL direct flashes of light from over the treatment chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane.

Each of the xenon flash lamps FL includes a rod-shaped glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second.

A flash power supply for supplying power to each of the flash lamps FL includes an IGBT (insulated-gate bipolar transistor) in addition to the aforementioned capacitor. By adjusting the waveform of the pulse applied to the gate of the IGBT, the light emission time of the flash lamps FL is definable between 0.1 and 100 milliseconds.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen lamp house 4 provided under the treatment chamber 6 includes an enclosure 41 incorporating the multiple (in the present preferred embodiment, 40) halogen lamps HL. The halogen lamps HL direct light from under the treatment chamber 6 through the lower chamber window 64 toward the heat treatment space 65.

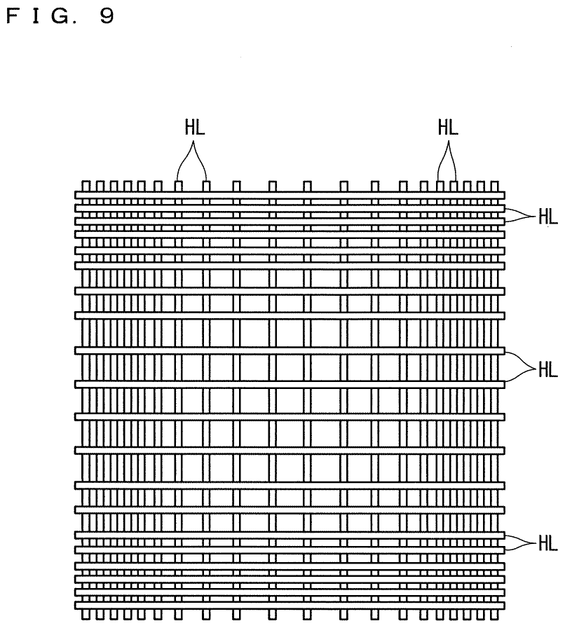

FIG. 9 is a plan view showing an arrangement of the multiple halogen lamps HL. In the present preferred embodiment, 20 halogen lamps HL are arranged in each of two tiers, i.e. upper and lower tiers. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 9, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen lamps HL.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the halogen lamps HL arranged in the upper tier and the longitudinal direction of the halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen lamp house 4 under the halogen lamps HL arranged in two tiers (FIG. 3). The reflector 43 reflects the light emitted from the halogen lamps HL toward the heat treatment space 65.

The heat treatment part 160 further includes, in addition to the aforementioned components, various cooling structures to prevent an excessive temperature rise in the halogen lamp house 4, the flash lamp house 5, and the treatment chamber 6 because of the heat energy generated from the halogen lamps HL and the flash lamps FL during the heat treatment of a semiconductor wafer W. As an example, a water cooling tube (not shown) is provided in the walls of the treatment chamber 6. Also, the halogen lamp house 4 and the flash lamp house 5 have an air cooling structure for forming a gas flow therein to exhaust heat. Air is supplied to a gap between the upper chamber window 63 and the lamp light radiation window 53 to cool down the flash lamp house 5 and the upper chamber window 63.

The controller 3 controls the aforementioned various operating mechanisms provided in the heat treatment apparatus 100. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part (e.g., a magnetic disk or an SSD) for storing control software, data and the like thereon. The CPU in the controller 3 executes a predetermined processing program, whereby the processes in the heat treatment apparatus 100 proceed. The controller 3 also controls the operations of the supply valve 84 and the exhaust valve 89 to adjust the supply and exhaust of gas to and from the treatment chamber 6. The controller 3 is shown in the indexer part 101 in FIG. 1. The present invention, however, is not limited to this. The controller 3 may be disposed in any position in the heat treatment apparatus 100.

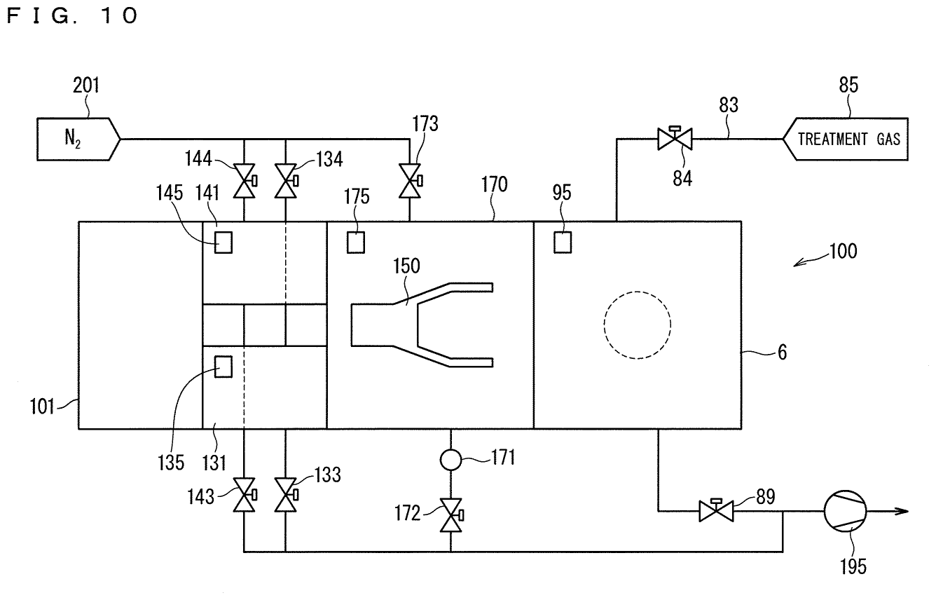

FIG. 10 is a schematic view of supply and exhaust systems for the heat treatment apparatus 100. The exhaust mechanism 190 (FIG. 3) includes a vacuum pump 195 connected through piping (exhaust lines) to the treatment chamber 6, the transport chamber 170, the first cool chamber 131, and the second cool chamber 141. On the other hand, a nitrogen supply source 201 is connected through piping (supply lines) to the transport chamber 170, the first cool chamber 131, and the second cool chamber 141. As mentioned above, the treatment gas supply source 85 for supplying various treatment gases is connected through the gas supply pipe 83 to the treatment chamber 6.

The exhaust valve 89 is provided in piping (the gas exhaust pipe 88) which connects the vacuum pump 195 and the treatment chamber 6 to each other, and the supply valve 84 is provided in the gas supply pipe 83. By opening the supply valve 84, a treatment gas is supplied to the treatment chamber 6. By opening the exhaust valve 89, the atmosphere in the treatment chamber 6 is exhausted. The treatment chamber 6 is provided with the pressure gauge 95, and the pressure in the treatment chamber 6 is measured by the pressure gauge 95. The pressure in the treatment chamber 6 is adjustable by controlling the opening and closing of the supply valve 84 and the exhaust valve 89 as appropriate. The pressure in the treatment chamber 6 is decreased if the flow rate of the atmosphere exhausted from the treatment chamber 6 is higher than the flow rate of the treatment gas supplied to the treatment chamber 6. On the other hand, the pressure in the treatment chamber 6 is increased if the flow rate of the atmosphere exhausted from the treatment chamber 6 is lower than the flow rate of the treatment gas supplied to the treatment chamber 6.

The transport chamber 170 which houses the transport robot 150 for transporting the semiconductor wafer W into and out of the treatment chamber 6 is connected to the treatment chamber 6. An exhaust valve 172 is provided in piping which connects the transport chamber 170 and the vacuum pump 195 to each other. By opening the exhaust valve 172, the atmosphere in the transport chamber 170 is exhausted. An APC (Automatic Pressure Control) valve 171 is also provided in the aforementioned piping. A supply valve 173 is provided in piping which connects the nitrogen supply source 201 and the transport chamber 170 to each other. By opening the supply valve 173, nitrogen gas is supplied into the transport chamber 170. The transport chamber 170 is provided with a pressure gauge 175, and the pressure in the transport chamber 170 is measured by the pressure gauge 175. The pressure in the transport chamber 170 is adjustable by controlling the opening and closing of the supply valve 173 and the exhaust valve 172 as appropriate. The APC valve 171 is provided in the piping which exhausts the atmosphere from the transport chamber 170. By setting a target pressure on the APC valve 171, the pressure in the transport chamber 170 is maintained at the target pressure.

The first cool chamber 131 and the second cool chamber 141 are connected in parallel to the transport chamber 170. An exhaust valve 133 is provided in piping which connects the first cool chamber 131 and the vacuum pump 195 to each other. By opening the exhaust valve 133, the atmosphere in the first cool chamber 131 is exhausted. A supply valve 134 is provided in piping which connects the nitrogen supply source 201 and the first cool chamber 131 to each other. By opening the supply valve 134, nitrogen gas is supplied into the first cool chamber 131. The first cool chamber 131 is provided with a pressure gauge 135. The pressure in the first cool chamber 131 is measured by the pressure gauge 135. The pressure in the first cool chamber 131 is adjustable by controlling the opening and closing of the supply valve 134 and the exhaust valve 133 as appropriate.

Similarly, an exhaust valve 143 is provided in piping which connects the second cool chamber 141 and the vacuum pump 195 to each other. By opening the exhaust valve 143, the atmosphere in the second cool chamber 141 is exhausted. A supply valve 144 is provided in piping which connects the nitrogen supply source 201 and the second cool chamber 141 to each other. By opening the supply valve 144, nitrogen gas is supplied into the second cool chamber 141. The second cool chamber 141 is provided with a pressure gauge 145. The pressure in the second cool chamber 141 is measured by the pressure gauge 145. The pressure in the second cool chamber 141 is adjustable by controlling the opening and closing of the supply valve 144 and the exhaust valve 143 as appropriate.

In the present preferred embodiment, the pressure adjustment is thus made to each of the transport chamber 170, the first cool chamber 131, and the second cool chamber 141 by supplying and exhausting gas thereto and therefrom independently and separately from the treatment chamber 6. No special supply or exhaust of gas is performed on the indexer part 101. The indexer part 101 is exposed to an atmosphere outside the heat treatment apparatus 100 (typically, an atmosphere in a clean room in which the heat treatment apparatus 100 is installed). Thus, the pressure in the indexer part 101 is always approximately atmospheric.

Next, a processing operation in the heat treatment apparatus 100 according to the present invention will be described. A base pressure (reference pressure) in the treatment chamber 6 of the heat treatment part 160 is set in the present preferred embodiment. The base pressure in the treatment chamber 6 is a slightly reduced pressure that is a fixed value lower than atmospheric pressure (approximately 101 kPa), and specifically has a predetermined value between 50 and 95 kPa. The base pressure is, for example, 80 kPa in the present preferred embodiment. A procedure for processing in the heat treatment apparatus 100 which will be described below proceeds under the control of the controller 3 over the operating mechanisms of the heat treatment apparatus 100.

First, while being stored in a carrier C, untreated semiconductor wafers (product wafers) W are placed on the first load port 110a or the second load port 110b of the indexer part 101. The transfer robot 120 takes the untreated semiconductor wafers W one by one out of the carrier C to transport each of the untreated semiconductor wafers W into the alignment chamber 231 of the alignment part 230. In the alignment chamber 231, a semiconductor wafer W is rotated in a horizontal plane about a vertical axis passing through the central portion of the semiconductor wafer W, and a notch or the like is optically detected, whereby the orientation of the semiconductor wafer W is adjusted.

Next, the transfer robot 120 of the indexer part 101 takes the orientation-adjusted semiconductor wafer W out of the alignment chamber 231 to transport the semiconductor wafer W into the first cool chamber 131 of the first cooling part 130 or the second cool chamber 141 of the second cooling part 140. In the present preferred embodiment, it is assumed that the semiconductor wafer W is transported into the first cool chamber 131 in the description below, but the same applies when the semiconductor wafer W is transported into the second cool chamber 141. The first cool chamber 131 temporarily holds the untreated semiconductor wafer W to be transported to the transport chamber 170.

When the semiconductor wafer W is transported into the first cool chamber 131, the gate valve 181 is opened and the gate valve 183 is closed. Thus, the atmosphere in the first cool chamber 131 is atmospheric, and the pressure in the first cool chamber 131 is also atmospheric.

After the semiconductor wafer W is transported into the first cool chamber 131, the gate valve 181 is closed to create an enclosed space inside the first cool chamber 131. Then, the supply valve 134 is opened, and the exhaust valve 133 is also opened. As a result, while nitrogen gas is supplied into the first cool chamber 131, an oxygen-containing atmosphere in the first cool chamber 131 is exhausted. Thus, the atmosphere in the first cool chamber 131 is gradually replaced with a nitrogen atmosphere, so that the oxygen concentration therein decreases. In addition, the pressure in the first cool chamber 131 gradually decreases from atmospheric pressure because the exhaust flow rate is higher than the nitrogen gas supply flow rate. The pressure in the first cool chamber 131 is measured by the pressure gauge 135. The controller 3 controls the supply valve 134 and the exhaust valve 133 so that the pressure in the first cool chamber 131 becomes equal to the aforementioned base pressure (80 kPa), based on the measurement result of the pressure gauge 135.

At the point in time when the pressure in the first cool chamber 131 decreasing from atmospheric pressure reaches the base pressure, the controller 3 controls the supply valve 134 and the exhaust valve 133 to maintain the pressure in the first cool chamber 131 at the fixed base pressure. Then, the gate valve 183 is opened, and the semiconductor wafer W in first cool chamber 131 is transported to the transport chamber 170 by the transport robot 150. The gate valve 181 remains closed.

The first cool chamber 131 and the second cool chamber 141 function as paths for transferring the semiconductor wafer W when the untreated semiconductor wafer W is transferred from the indexer part 101 via the first cool chamber 131 or the second cool chamber 141 to the transport chamber 170. In the present preferred embodiment, the first cool chamber 131 and the second cool chamber 141 function also as load lock chambers for the pressure adjustment from atmospheric pressure to the base pressure of the treatment chamber 6.

While the supply valve 173 is opened to supply nitrogen gas into the transport chamber 170, the exhaust valve 172 is opened to exhaust the atmosphere from the transport chamber 170. A nitrogen atmosphere with a low oxygen concentration is created in the transport chamber 170, and the pressure in the transport chamber 170 is always maintained at the base pressure by the APC valve 171. For this reason, the gate valve 183 is opened after the pressure in the first cool chamber 131 is decreased to the base pressure.

After taking the semiconductor wafer W out of the first cool chamber 131, the transport robot 150 pivots so as to face toward the heat treatment part 160. Subsequently, the gate valve 185 opens the space between the treatment chamber 6 and the transport chamber 170. At this time, the pressure in the treatment chamber 6 is also the base pressure. Then, the transport robot 150 transports the untreated semiconductor wafer W into the treatment chamber 6. At this time, if a preceding semiconductor wafer W subjected to the heating treatment is present in the treatment chamber 6, the untreated semiconductor wafer W is transported into the treatment chamber 6 after one of the transport hands 151a and 151b takes out the semiconductor wafer W subjected to the heating treatment. In this manner, the semiconductor wafers W are interchanged. Thereafter, the gate valve 185 closes the space between the treatment chamber 6 and the transport chamber 170.

The semiconductor wafer W transported into the treatment chamber 6 is preheated by the halogen lamps HL, and is thereafter subjected to the flash heating treatment by flash irradiation from the flash lamps FL. The flash heating treatment in the present preferred embodiment is carried out, for example, in a reduced-pressure ammonia atmosphere.

After the completion of the flash heating treatment, the gate valve 185 opens the space between the treatment chamber 6 and the transport chamber 170 again. At this time, the pressure in the treatment chamber 6 is also the base pressure. Then, the transport robot 150 transports the semiconductor wafer W subjected to the flash heating treatment from the treatment chamber 6 to the transport chamber 170. After taking out the semiconductor wafer W, the transport robot 150 pivots from the treatment chamber 6 so as to face toward the first cool chamber 131 or the second cool chamber 141. The gate valve 185 closes the space between the treatment chamber 6 and the transport chamber 170.

Thereafter, the transport robot 150 transports the semiconductor wafer W subjected to the heating treatment into the first cool chamber 131 of the first cooling part 130 or the second cool chamber 141 of the second cooling part 140. In the present preferred embodiment, it is assumed that the semiconductor wafer W subjected to the heating treatment is transported into the second cool chamber 141 in the description below, but the same applies when the semiconductor wafer W subjected to the heating treatment is transported into the first cool chamber 131. The second cool chamber 141 temporarily holds and cools the semiconductor wafer W subjected to the heating treatment and transported from the transport chamber 170.

When the semiconductor wafer W is transported into the second cool chamber 141, the supply valve 144 and the exhaust valve 143 are opened to create a nitrogen atmosphere in the second cool chamber 141. The controller 3 controls the supply valve 144 and the exhaust valve 143 so that the pressure in the second cool chamber 141 is maintained at the base pressure. In this state, the gate valve 184 is opened, whereas the gate valve 182 is closed.

After the semiconductor wafer W subjected to the heating treatment is transported into the second cool chamber 141, the gate valve 184 is closed to create an enclosed space inside the second cool chamber 141. In the second cool chamber 141, the semiconductor wafer W subjected to the flash heating treatment is cooled. The semiconductor wafer W is cooled to near room temperatures in the nitrogen atmosphere in the second cool chamber 141 because the temperature of the entire semiconductor wafer W is relatively high when the semiconductor wafer W is transported out of the treatment chamber 6 of the heat treatment part 160.

While the cooling is performed on the semiconductor wafer W, the nitrogen gas supply flow rate is made higher than the exhaust flow rate, so that the pressure in the second cool chamber 141 is returned from the base pressure to atmospheric pressure. Specifically, the controller 3 controls the supply valve 144 and the exhaust valve 143 so that the pressure in the second cool chamber 141 becomes equal to atmospheric pressure, based on the measurement result of the pressure gauge 145.

After the pressure in the second cool chamber 141 is returned to atmospheric pressure and a predetermined cooling time period has elapsed, the gate valve 182 is opened. Then, the transfer robot 120 transports the cooled semiconductor wafer W out of the second cool chamber 141, and returns the cooled semiconductor wafer W back to the carrier C. After a predetermined number of treated semiconductor wafers W are stored in the carrier C, the carrier C is transported from the first load port 110a or the second load port 110b of the indexer part 101 to the outside.

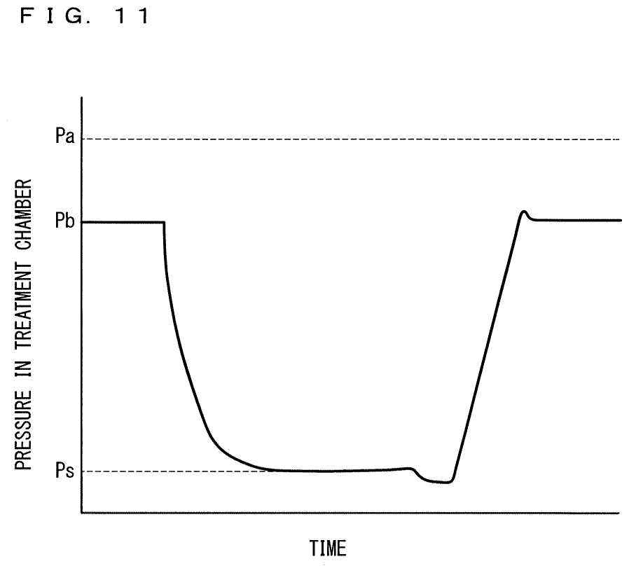

The description on the heating treatment in the heat treatment part 160 will be continued. FIG. 11 is a graph showing pressure variations in the treatment chamber 6. Even before the semiconductor wafer W is transported into the treatment chamber 6, the pressure in the treatment chamber 6 is maintained at a base pressure Pb that is a fixed value lower than atmospheric pressure Pa. Specifically, the supply valve 84 is opened to supply nitrogen gas into the treatment chamber 6, and the exhaust valve 89 is opened to exhaust the atmosphere in the treatment chamber 6. The pressure in the treatment chamber 6 is measured by the pressure gauge 95. The controller 3 controls the supply valve 84 and the exhaust valve 89 so that the pressure in the treatment chamber 6 is maintained at the base pressure Pb, based on the measurement result of the pressure gauge 95. The controller 3 controls the valve 192 and the mechanism for exhausting the atmosphere around the drivers of the transfer mechanism 10 in the same manner as the exhaust valve 89 so that the pressure in the treatment chamber 6 is maintained at the base pressure Pb.

The pressure in the transport chamber 170 is always maintained at the base pressure by the APC valve 171. For this reason, when the pressure in the treatment chamber 6 is equal to the base pressure Pb, the gate valve 185 may be opened to open the transport opening 66. The gate valve 185 opens the transport opening 66, and the transport robot 150 transports a semiconductor wafer W to be treated through the transport opening 66 into the heat treatment space 65 of the treatment chamber 6. In other words, the transfer of the semiconductor wafer W between the transport chamber 170 and the treatment chamber 6 is carried out at the base pressure Pb.

The transport robot 150 moves the transport hand 151a (or the transport hand 151b) holding the untreated semiconductor wafer W forward to a position lying immediately over the holder 7, and stops the transport hand 151a (or the transport hand 151b) thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the untreated semiconductor wafer W is placed on the lift pins 12, the transport robot 150 causes the transport hand 151a to move out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface to be subjected to the flash heating treatment is the upper surface. A predetermined distance is defined between the back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is transported into the treatment chamber 6 and the transport opening 66 is closed by the gate valve 185 to cause the heat treatment space 65 to become an enclosed space, the pressure in the treatment chamber 6 is further reduced from the base pressure Pb. Specifically, the controller 3 controls the supply valve 84 and the exhaust valve 89 so that the pressure in the treatment chamber 6 is reduced from the base pressure Pb to a target treatment pressure Ps, based on the measurement result of the pressure gauge 95. The treatment pressure Ps is lower than the base pressure Pb, and has a predetermined value between 5 and 10 kPa, for example.

While the pressure in the treatment chamber 6 is reduced, a gas mixture of ammonia and nitrogen is supplied from the treatment gas supply source 85 into the treatment chamber 6. This forms an ammonia atmosphere in a reduced-pressure condition in the heat treatment space 65 of the treatment chamber 6. If the exhaust flow rate is higher than the supply flow rate of the gas mixture of ammonia and nitrogen, the ammonia atmosphere can be formed in the treatment chamber 6 while the pressure in the treatment chamber 6 is reduced.

After the ammonia atmosphere is formed in the treatment chamber 6 and the pressure in the treatment chamber 6 is reduced to the treatment pressure Ps, the 40 halogen lamps HL turn on simultaneously to start preheating (or assist-heating). Halogen light emitted from the halogen lamps HL is transmitted through the lower chamber window 64 and the susceptor 74 both made of quartz, and impinges upon the lower surface of the semiconductor wafer W. By receiving light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W is measured by the radiation thermometer 20 when the halogen lamps HL perform the preheating. Specifically, the radiation thermometer 20 receives infrared radiation emitted from the lower surface of the semiconductor wafer W held by the susceptor 74 through the opening 78 to measure the temperature of the semiconductor wafer W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured by the radiation thermometer 20.

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured by the radiation thermometer 20 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in a peripheral portion thereof where heat dissipation is liable to occur than in a central portion thereof. However, the halogen lamps HL in the halogen lamp house 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating.

The flash lamps FL irradiate the front surface of the semiconductor wafer W with a flash of light at the point in time when a predetermined time period has elapsed since the temperature of the semiconductor wafer W reached the preheating temperature T1. At this time, part of the flash of light emitted from the flash lamps FL travels directly toward the interior of the treatment chamber 6. The remainder of the flash of light is reflected once from the reflector 52, and then travels toward the interior of the treatment chamber 6. The irradiation of the semiconductor wafer W with such flashes of light achieves the flash heating of the semiconductor wafer W.

The flash heating, which is achieved by the emission of a flash of light from the flash lamps FL, is capable of increasing the front surface temperature of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The front surface of the semiconductor wafer W is irradiated with such a flash of light which is extremely short in irradiation time and high in intensity, whereby the front surface temperature of the semiconductor wafer W momentarily increases to a treatment temperature T2. The treatment temperature T2 is higher than the preheating temperature T1. Upon reaching the treatment temperature T2, the front surface temperature of the semiconductor wafer W then decreases rapidly. The flash heating of the semiconductor wafer W in an ammonia atmosphere causes surface treatment (e.g., nitriding) to be performed on the semiconductor wafer W.

After a predetermined time period has elapsed since the completion of the flash heating treatment, the halogen lamps HL turn off. This causes the temperature of the semiconductor wafer W to decrease rapidly from the preheating temperature T1. The radiation thermometer 20 measures the temperature of the semiconductor wafer W which is on the decrease. The result of measurement is transmitted to the controller 3. After the completion of the flash heating treatment, the supply valve 84 is closed once, with the exhaust valve 89 kept open, under the control of the controller 3 to exhaust ammonia from the treatment chamber 6. Thereafter, the supply valve 84 is opened again to supply nitrogen gas from the treatment gas supply source 85 into the treatment chamber 6, thereby returning the pressure in the treatment chamber 6 to the base pressure Pb. To be more precise, the controller 3 controls the supply valve 84 and the exhaust valve 89 so that the pressure in the treatment chamber 6 is returned to the base pressure Pb, based on the measurement result of the pressure gauge 95.

After the pressure in the treatment chamber 6 is returned to the base pressure Pb, the controller 3 monitors whether the temperature of the semiconductor wafer W is decreased to a predetermined temperature or not, based on the result of measurement by means of the radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport hand 151b (or the transport hand 151a) of the transport robot 150 transports the treated semiconductor wafer W placed on the lift pins 12 to the transport chamber 170. At this time, the gate valve 185 can be opened because the pressure in the transport chamber 170 and the pressure in the treatment chamber 6 are both equal to the base pressure Pb. The transfer of the semiconductor wafer W from the treatment chamber 6 to the transport chamber 170 is also carried out at the base pressure Pb.

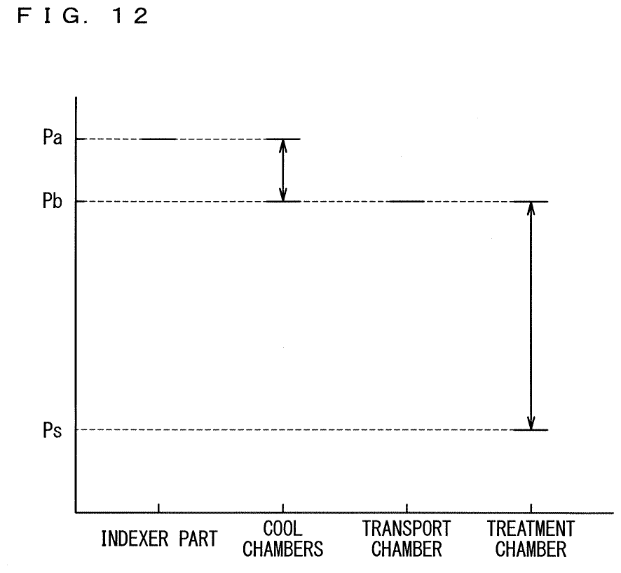

FIG. 12 is a graph showing a relationship between the pressures in the indexer part 101, the first and second cool chambers 131 and 141, the transport chamber 170, and the treatment chamber 6. It should be noted that the first cool chamber 131 and the second cool chamber 141, which are equivalent chambers that perform the same treatment, are generically referred to simply as “cool chambers” in FIG. 12. The pressure in the indexer part 101, which is open to the atmosphere, is always the atmospheric pressure Pa. The pressure in the transport chamber 170 is always maintained at the base pressure Pb. The pressure in the first and second cool chambers 131 and 141, which connect the transport chamber 170 and the indexer part 101 to each other, varies between the atmospheric pressure Pa and the base pressure Pb. On the other hand, the pressure in the treatment chamber 6 of the heat treatment part 160 varies between the base pressure Pb and the treatment pressure Ps.

As shown in FIGS. 11 and 12, the pressure in the treatment chamber 6 is always maintained at or below the base pressure Pb, which is a fixed value lower than the atmospheric pressure Pa, under the control of the controller 3 in the present preferred embodiment. Specifically, the pressure in the treatment chamber 6 is set to the base pressure Pb when the semiconductor wafer W is transported into and out of the treatment chamber 6, and is less than the base pressure Pb when the heating treatment is performed on the semiconductor wafer W. In short, the reference pressure in the treatment chamber 6 is made lower than the atmospheric pressure Pa in the present preferred embodiment although the reference pressure in the treatment chamber 6 that performs the flash heating treatment is typically the atmospheric pressure Pa.

Even if pressure variations overshoot more or less from the base pressure Pb serving as a reference when the pressure in the treatment chamber 6 is returned after the flash heating treatment as shown in FIG. 11, the pressure in the treatment chamber 6 does not exceed the atmospheric pressure Pa because the pressure in the treatment chamber 6 is always lower than the atmospheric pressure Pa. As a result, the inside of the treatment chamber 6 is prevented from being under a positive pressure relative to the outside of the heat treatment apparatus 100 even if variations in pressure in the treatment chamber 6 overshoot. Thus, the inside of the treatment chamber 6 is always under a negative pressure relative to the outside of the heat treatment apparatus 100. This prevents ammonia or other harmful gases from leaking out of the treatment chamber 6 to the outside of the heat treatment apparatus 100.

Even in the present preferred embodiment, O-rings for sealing between the upper chamber window 63 and the chamber side portion 61 and between the lower chamber window 64 and the chamber side portion 61, for example, deteriorate in a relatively short time in some cases because the pressure in the treatment chamber 6 is repeatedly reduced to the treatment pressure Ps and returned to the base pressure Pb each time a single semiconductor wafer W is treated. In the present preferred embodiment, the pressure in the treatment chamber 6 is always lower than the atmospheric pressure Pa, and the inside of the treatment chamber 6 is always under a negative pressure relative to the outside of the heat treatment apparatus 100. Even if the O-rings or other parts deteriorate and break, the gas in the treatment chamber 6 is prevented from leaking through the broken section to the outside.

The base pressure Pb which is the reference pressure in the treatment chamber 6 is between 50 and 95 kPa. Thus, even if barometric pressure outside the heat treatment apparatus 100 decreases more or less due to the influence of a typhoon or the like, the inside of the treatment chamber 6 is always under a negative pressure relative to the outside of the heat treatment apparatus 100. This prevents gases from leaking out of the treatment chamber 6 to the outside of the heat treatment apparatus 100.

When the untreated semiconductor wafer W is held in the first cool chamber 131 after transported into the first cool chamber 131, the pressure in the first cool chamber 131 is reduced from the atmospheric pressure Pa to the base pressure Pb. On the other hand, when the semiconductor wafer W subjected to the heating treatment is held in the second cool chamber 141 after transported into the second cool chamber 141, the pressure in the second cool chamber 141 is returned from the base pressure Pb to the atmospheric pressure Pa. In other words, the reference pressure in the treatment chamber 6 is the base pressure Pb lower than the atmospheric pressure Pa, whereas the pressure in the indexer part 101 which is open to the atmosphere is the atmospheric pressure Pa, and the differential pressure therebetween is adjusted in the first cool chamber 131 and the second cool chamber 141 (FIG. 12). The adjustment of the differential pressure can also be made in the transport chamber 170. However, the volume of the first and second cool chambers 131 and 141 is as small as approximately 1/10 that of the transport chamber 170. Thus, the adjustment of the differential pressure in the first and second cool chambers 131 and 141 allows the pressure adjustment in a shorter time using a smaller amount of nitrogen gas than the adjustment of the differential pressure in the transport chamber 170.

Further, in the present preferred embodiment, the pressure in the treatment chamber 6 is reduced from the base pressure Pb lower than the atmospheric pressure Pa to the treatment pressure Ps during the heating treatment of the semiconductor wafer W in the treatment chamber 6 of the heat treatment part 160, and is returned to the base pressure Pb after the heating treatment. This shortens the time required for pressure adjustment in the present preferred embodiment to result in improved throughput, as compared with the process of reducing the pressure from the atmospheric pressure Pa to the treatment pressure Ps and then returning to the atmospheric pressure Pa after the heating treatment.

While the preferred embodiment according to the present invention has been described hereinabove, various modifications of the present invention in addition to those described above may be made without departing from the scope and spirit of the invention. For example, the pressure in the transport chamber 170 is always equal to the base pressure Pb of the treatment chamber 6 in the aforementioned preferred embodiment. However, the pressure in the transport chamber 170 may be slightly higher than the base pressure Pb of the treatment chamber 6. Specifically, for example, when the base pressure Pb of the treatment chamber 6 is 79 kPa, the pressure in the transport chamber 170 may be 81 kPa. This causes the transport chamber 170 to be always under a positive pressure relative to the treatment chamber 6, thereby preventing gases from leaking from the treatment chamber 6 to the transport chamber 170. It is preferable to prevent gas leakage from the treatment chamber 6 to the transport chamber 170 as much as possible, although not so strict as compared with gas leakage to the outside of the heat treatment apparatus 100.

In the layout of the heat treatment apparatus 100 shown in FIG. 1, a chamber for a flaw detection part for detecting flaws on the back surface of the semiconductor wafer W, for example, may be connected to the opposite side (the negative Y side) of the indexer part 101 from the alignment part 230. Even such a configuration produces effects similar to those in the aforementioned preferred embodiment if the reference pressure in the treatment chamber 6 is lower than the atmospheric pressure Pa.

In the aforementioned preferred embodiment, ammonia is supplied as the treatment gas into the treatment chamber 6. The present invention, however, is not limited thereto. The treatment gas supplied into the treatment chamber 6 may be ozone, oxygen, nitrogen oxides, or the like. Even when these treatment gases are used, the inside of the treatment chamber 6 is always under a negative pressure relative to the outside of the heat treatment apparatus 100, which in turn prevents harmful gases from leaking out of the treatment chamber 6.

Although the 30 flash lamps FL are provided in the flash lamp house 5 in the aforementioned preferred embodiment, the present invention is not limited to this. Any number of flash lamps FL may be provided. The flash lamps FL are not limited to the xenon flash lamps, but may be krypton flash lamps. Also, the number of halogen lamps HL provided in the halogen lamp house 4 is not limited to 40. Any number of halogen lamps HL may be provided.

In the aforementioned preferred embodiment, the filament-type halogen lamps HL are used as continuous lighting lamps that emit light continuously for not less than one second to preheat the semiconductor wafer W. The present invention, however, is not limited to this. In place of the halogen lamps HL, discharge type arc lamps (e.g., xenon arc lamps) or LED lamps may be used as the continuous lighting lamps to perform the preheating.

While the invention has been shown and described in detail, the foregoing description is in all aspects illustrative and not restrictive. It is therefore understood that numerous modifications and variations can be devised without departing from the scope of the invention.

What is claimed is:

1. A heat treatment apparatus for heating a substrate by irradiating the substrate with light, comprising:
a treatment chamber for receiving a substrate therein to perform heating treatment on the substrate;
a holder for holding the substrate in said treatment chamber;
a light source for irradiating the substrate received in said treatment chamber with light;
a gas supply part for supplying a treatment gas to said treatment chamber;
an exhaust part for exhausting an atmosphere from said treatment chamber; and
a controller for controlling said gas supply part and said exhaust part so that a target pressure is reached in said treatment chamber,
wherein said controller controls said gas supply part and said exhaust part so that pressure in said treatment chamber is always maintained at or below a reference pressure that is a fixed value lower than atmospheric pressure and so that the pressure in said treatment chamber is a treatment pressure lower than said reference pressure during the heating treatment of the substrate.

2. The heat treatment apparatus according to claim 1,
wherein said controller controls said gas supply part and said exhaust part so that the pressure in said treatment chamber is reduced from said reference pressure to said treatment pressure after the substrate is transported into said treatment chamber and so that the pressure in said treatment chamber is returned from said treatment pressure to said reference pressure after the heating treatment.

3. The heat treatment apparatus according to claim 1,
wherein said reference pressure is between 50 and 95 kPa.

4. The heat treatment apparatus according to claim 1, further comprising
a transport chamber connected to said treatment chamber and for housing therein a transport robot for transporting a substrate into and out of said treatment chamber,
wherein pressure in said transport chamber is always maintained at said reference pressure, and transfer of the substrate between said transport chamber and said treatment chamber is performed at said reference pressure.

5. The heat treatment apparatus according to claim 4, further comprising
a cool chamber connected to said transport chamber and for temporarily holding an untreated substrate to be transported to said transport chamber and for temporarily holding and cooling a substrate subjected to the heating treatment and transported from said transport chamber,
wherein said cool chamber has a volume smaller than that of said transport chamber, and
wherein pressure in said cool chamber is reduced from the atmospheric pressure to said reference pressure when the untreated substrate is held in said cool chamber after transported into said cool chamber, and the pressure in said cool chamber is returned from said reference pressure to the atmospheric pressure when the substrate subjected to the heating treatment is held in said cool chamber after transported into said cool chamber.

6. The heat treatment apparatus according to claim 1,
wherein said light source includes a flash lamp for irradiating a front surface of the substrate held by said holder with a flash of light.

7. A method of heating a substrate by irradiating the substrate with light, said method comprising the steps of:
(a) receiving a substrate in a treatment chamber;
(b) reducing pressure in said treatment chamber receiving the substrate therein;
(c) irradiating said substrate with light; and
(d) returning the pressure in said treatment chamber,
wherein the pressure in said treatment chamber is always maintained at or below a reference pressure that is a fixed value lower than atmospheric pressure, and
wherein the pressure in said treatment chamber in said step (c) is a treatment pressure lower than said reference pressure.

8. The method according to claim 7,
wherein the pressure in said treatment chamber is reduced from said reference pressure to said treatment pressure in said step (b), and
wherein the pressure in said treatment chamber is returned from said treatment pressure to said reference pressure in said step (d).

9. The method according to claim 7,
wherein said reference pressure is between 50 and 95 kPa.

10. The method according to claim 7,
wherein a transport robot provided in a transport chamber connected to said treatment chamber transports a substrate into and out of said treatment chamber, and
wherein pressure in said transport chamber is always maintained at said reference pressure, and transfer of the substrate between said transport chamber and said treatment chamber is performed at said reference pressure.

11. The method according to claim 10,
wherein a cool chamber connected to said transport chamber temporarily holds an untreated substrate to be transported to said transport chamber and temporarily holds and cools a substrate subjected to the heating treatment and transported from said transport chamber,
wherein said cool chamber has a volume smaller than that of said transport chamber, and
wherein pressure in said cool chamber is reduced from the atmospheric pressure to said reference pressure when the untreated substrate is held in said cool chamber after transported into said cool chamber, and the pressure in said cool chamber is increased from said reference pressure to the atmospheric pressure when the substrate subjected to the heating treatment is held in said cool chamber after transported into said cool chamber.

12. The method according to claim 7,
wherein a front surface of the substrate is irradiated with a flash of light from a flash lamp in said step (c).
